(19) United States
(12) Patent Application Publication
(10) Pub. No.: US 2025/0236946 A1
(43) Pub. Date: Jul. 24, 2025

(54) VACUUM TREATMENT APPARATUS AND VACUUM TREATMENT METHOD

(71) Applicant: ULVAC, INC., Chigasaki-shi (JP)

(72) Inventors: Takahito KIMOTO, Chigasaki-shi (JP); Takuya FUJII, Chigasaki-shi (JP); Junichi SAKAMOTO, Chigasaki-shi (JP); Masatoshi SATO, Chigasaki-shi (JP)

(21) Appl. No.: 18/987,741

(22) Filed: Dec. 19, 2024

(30) Foreign Application Priority Data
Jan. 18, 2024 (JP) 2024-005818

(51) Int. Cl. C23C 14/14; C23C 14/58; H01M 4/04

(52) U.S. Cl. CPC C23C 14/14; C23C 14/5846; H01M 4/0423

(57) ABSTRACT

A vacuum treatment apparatus includes a deposition unit and a plasma treatment unit. The deposition unit includes an evaporation source including a lithium metal and forms a lithium metal film on a base material. The plasma treatment unit exposes a surface of the lithium metal film formed on the base material to a discharge gas obtained by discharging a gas containing carbon and oxygen, and forms a lithium carbonate layer on the surface.

### CROSS-REFERENCE TO RELATED APPLICATION

This application claims the benefit of Japanese Priority Patent Application JP 2024-005818 filed Jan. 18, 2024, the entire contents of which are incorporated herein by reference.

### BACKGROUND

The present invention relates to a vacuum treatment apparatus and a vacuum treatment method.

With the recent development of mobile devices such as cellular phones and smart phones, lithium batteries installed in those devices have been attracting attention. In the manufacturing processes of lithium batteries, the process of forming a lithium metal on a base material is particularly important, and various technologies have been proposed in the past.

For example, there is a technology to evaporate a lithium metal in a vacuum chamber and deposit scattered particles on a base material to thereby form a lithium metal on the base material. In addition, there is a technology to form a protective layer made of lithium carbonate on a surface of a lithium metal film to suppress degradation of the lithium metal film (see, for example, WO2019/156005).

### SUMMARY

In the technologies described above, a lithium carbonate layer is formed on the surface of the lithium metal film by exposing the surface of the lithium metal film to a carbon dioxide gas. There is a demand for further speed-up in the technologies to form the lithium carbonate layer on the surface of the lithium metal film.

In view of the circumstances as described above, it is desirable to provide a vacuum treatment apparatus and a vacuum treatment method that achieve further speed-up in the technologies to form a lithium carbonate layer on a surface of a lithium metal film.

According to an embodiment of the present invention, there is provided a vacuum treatment apparatus including a deposition unit and a plasma treatment unit.

The deposition unit includes an evaporation source including a lithium metal and forms a lithium metal film on a base material.

The plasma treatment unit exposes a surface of the lithium metal film formed on the base material to a discharge gas obtained by discharging a gas containing carbon and oxygen, and forms a lithium carbonate layer on the surface.

Such a vacuum treatment apparatus makes it possible to modify the surface of the lithium metal film formed on the base material into a lithium carbonate layer more quickly.

In the vacuum treatment apparatus, the lithium carbonate layer may be formed on the surface while the base material is being conveyed from the deposition unit toward the plasma treatment unit, and a conveyance speed at which the base material is conveyed may be 1 m/min or more.

Such a vacuum treatment apparatus makes it possible to modify the surface of the lithium metal film formed on the base material into a lithium carbonate layer more quickly.

In the vacuum treatment apparatus, the base material may be foil-like, the vacuum treatment apparatus may further include: a wind-off roller that winds off the base material; a wind roller that winds the base material; and a main roller provided between the wind-off roller and the wind roller in a conveyance direction in which the base material is conveyed, and winds and conveys the base material, and the plasma treatment unit may be disposed between the main roller and the wind roller in the conveyance direction.

Such a vacuum treatment apparatus makes it possible to modify the surface of the lithium metal film formed on the base material into a lithium carbonate layer more quickly.

In the vacuum treatment apparatus, the plasma treatment unit may include at least one discharge electrode that extends in a width direction of the base material and faces at least one of a first main surface of the base material or a second main surface opposite to the first main surface, a gas supply unit that supplies the gas to an internal space of the plasma treatment unit, and a power supply that supplies discharge power to the discharge electrode.

Such a vacuum treatment apparatus makes it possible to modify the surface of the lithium metal film formed on the base material into a lithium carbonate layer more quickly.

In the vacuum treatment apparatus, a surface of the discharge electrode may include C, Mg, Al, Si, Ti, Fe, Ni, Zn, Ag, Sn, and an alloy of those metals.

Such a vacuum treatment apparatus makes it possible to modify the surface of the lithium metal film formed on the base material into a lithium carbonate layer more quickly.

According to an embodiment of the present invention, there is provided a vacuum treatment method including: forming a lithium metal film on a base material by using an evaporation source including a lithium metal; and exposing a surface of the lithium metal film formed on the base material to a discharge gas obtained by discharging a gas containing carbon and oxygen, and forms a lithium carbonate layer on the surface.

Such a vacuum treatment method makes it possible to modify the surface of the lithium metal film formed on the base material into a lithium carbonate layer more quickly.

In the vacuum treatment method, the lithium carbonate layer may be formed on the surface continuously after the lithium metal film is formed on the base material with a reduced pressure state being maintained.

Such a vacuum treatment method makes it possible to modify the surface of the lithium metal film formed on the base material into a lithium carbonate layer more quickly.

In the vacuum treatment method, the lithium carbonate layer may be formed on the surface while the base material is being conveyed from a deposition unit toward a plasma treatment unit, and a conveyance speed at which the base material is conveyed may be set to 1 m/min or more.

Such a vacuum treatment method makes it possible to modify the surface of the lithium metal film formed on the base material into a lithium carbonate layer more quickly.

In the vacuum treatment method, the base material may be foil-like, and the lithium carbonate layer may be formed on the surface by a roll-to-roll method.

Such a vacuum treatment method makes it possible to modify the surface of the lithium metal film formed on the base material into a lithium carbonate layer more quickly.

In the vacuum treatment method, the lithium metal film having a thickness of 1 μm or more and 20 μm or less may be formed on the base material, and the lithium carbonate layer having a thickness of 5 nm or more and 30 nm or less may be formed.

Such a vacuum treatment method makes it possible to modify the surface of the lithium metal film formed on the base material into a lithium carbonate layer more quickly.

As described above, according to the present invention, a vacuum treatment apparatus and a vacuum treatment method are provided, which achieve further speed-up in the technologies to form a lithium carbonate layer on a surface of a lithium metal film.

These and other objects, features and advantages of the present disclosure will become more apparent in light of the following detailed description of best mode embodiments thereof, as illustrated in the accompanying drawings.

### BRIEF DESCRIPTION OF DRAWINGS

FIGS. 1A, 1B, and 1C are schematic cross-sectional views showing the outline of the procedure by which a surface of a lithium metal film is modified into a lithium carbonate layer in this embodiment;

FIG. 2 is a schematic configuration diagram showing an example of a vacuum treatment apparatus of this embodiment;

FIG. 3 is a schematic configuration diagram showing another example of the vacuum treatment apparatus of this embodiment;

FIGS. 4A and 4B are schematic cross-sectional views showing other examples of a plasma treatment chamber of this embodiment; and

FIG. 5 is a schematic cross-sectional view showing another example of the plasma treatment chamber of this embodiment.

### DETAILED DESCRIPTION OF EMBODIMENTS

Hereinafter, an embodiment of the present invention will be described with reference to the drawings. XYZ coordinates may be introduced in the figures as necessary. Further, the same reference symbols may be provided to the same members or the members having the same functions, and after those members are described, the description may be omitted as appropriate. In addition, the numerical values to be shown below are examples and are not limited to those examples.

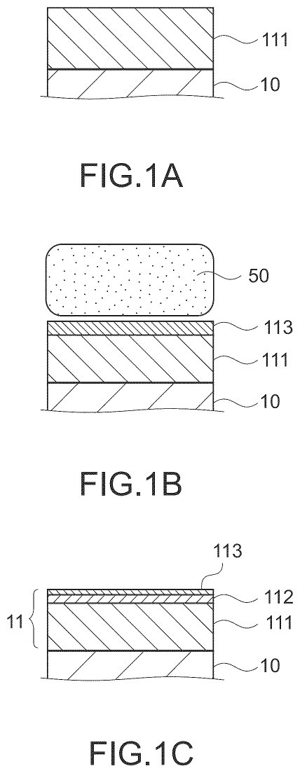

FIGS. 1A, 1, and 1C are schematic cross-sectional views showing the outline of the procedure by which a surface of a lithium metal film is modified into a lithium carbonate layer in this embodiment. The lithium metal film is applied, for example, as part of components of a lithium ion battery.

First, as shown in FIG. 1A, a lithium metal film 111 is formed on a surface of a base material by deposition treatment. Here, a physical vapor deposition (PVD) method is applied as the deposition treatment. For example, a vacuum vapor deposition method using an evaporation source including a lithium metal is applied as the deposition treatment. Examples of techniques applied as the vacuum vapor deposition include resistance heating, induction heating, and electron beam heating. Examples of deposition methods may include a batch method (in-line method) and a roll-to-roll method.

Further, “base material” means a foil-like base material on which the lithium metal film 111 is deposited. The base material may be flexible or rigid. For example, the base material can be a metal foil such as a copper foil, a nickel foil, an iron foil, or a stainless steel foil, or a resin film made of polyethylene terephthalate (PET), polyethylene naphthalate (PEN), polyethylene (PE), polypropylene (PP), polyimide (PI), or polyphenylene sulfide (PPS). Further, if a resin film is used as the base material, a film of copper, nickel, iron, or an alloy of those metals may be deposited at a thickness of 10 nm (nanometer) or more and 1000 nm or less on one or both surfaces of the resin film.

The thickness of the lithium metal film 111 is, for example, 1 μm (micrometer) or more and 20 μm or less. If the thickness of the lithium metal film 111 is smaller than 1 μm, desired battery characteristics are not obtained, and if the thickness of the lithium metal film 111 is larger than 20 μm, productivity may become poor, which is not desirable.

Next, as shown in FIG. 1B, the surface of the lithium metal film 111 is carbonated, and a lithium carbonate layer 113 having a predetermined thickness is formed. For example, the lithium carbonate layer 113 is formed on the surface of the lithium metal film 111 by directly exposing the surface of the lithium metal film 111 formed on the base material 10 to a discharge gas (plasma) 50 obtained by discharging a gas containing carbon and oxygen.

Here, examples of the gas containing carbon and oxygen in this embodiment include carbon monoxide; carbon dioxide; hydrocarbons and oxygen or ozone; and combinations of those gases. Alternatively, the gas containing carbon and oxygen may be a mixed gas containing at least one of carbon monoxide; carbon dioxide; hydrocarbons and oxygen or ozone; or combinations of those gases, and a noble gas of argon or helium. The discharge gas 50 includes a gas in which carbon monoxide; carbon dioxide; or hydrocarbons and oxygen or ozone is ionized, and active species (radicals) of carbon monoxide, carbon dioxide, or hydrocarbons.

For example, in this embodiment, the lithium carbonate layer 113 is formed on the surface of the lithium metal film 111 continuously after the lithium metal film 111 is formed on the base material 10 with a reduced pressure state (in-situ) being maintained. In other words, the surface of the lithium metal film 111 is directly carbonated by the discharge gas 50 without being subjected to atmospheric components or moisture (without being exposed to atmospheric components or moisture).

For example, a deposition chamber (deposition unit) in which the lithium metal film 111 is deposited and a treatment chamber (plasma treatment unit) in which the surface of the lithium metal film 111 is carbonated are adjacent to each other via a gate valve, or the deposition chamber and the treatment chamber are continuously adjacent to each other in the same vacuum chamber. Those configurations are described below.

Upon elapse of a predetermined time after the surface of the lithium metal film 111 is modified into the lithium carbonate layer 113, a lithium oxide film 112 is formed between the lithium metal film 111 and the lithium carbonate layer 113. FIG. 1C shows this state. For example, one example of a factor that causes the formation of the lithium oxide film 112 is the decomposition of part of the lithium carbonate layer 113 that contacts the lithium metal film 111, resulting in the formation of the lithium oxide film 112 between the lithium metal film 111 and the lithium carbonate layer 113. Factors that cause the formation of the lithium oxide film 112 are not limited to this example.

In this state (FIG. 1C), the lithium carbonate layer 113 has a thickness of, for example, 5 nm or more and 30 nm or less. If the lithium carbonate layer 113 has a thickness smaller than 5 nm, the effect of suppressing the degradation of the lithium metal film is reduced. If the lithium carbonate layer 113 has a thickness larger than 30 nm, desired battery characteristics are not obtained due to the electrical resistance of the lithium carbonate layer. Further, the lithium oxide film 112 has a thickness of, for example, 50 nm or more and 300 nm or less. If the lithium oxide film 112 has a thickness exceeding 100 nm, desired battery characteristics are not obtained.

A laminated film 11 formed on the base material 10 is used, for example, as a negative electrode for a lithium metal battery. The laminated film 11 (lithium electrode) includes the lithium metal film 111 formed on the base material 10, the lithium carbonate layer 113, and the lithium oxide film 112 interposed between the lithium metal film 111 and the lithium carbonate layer 113. The lithium metal film 111 is covered with the lithium carbonate layer 113, which effectively inhibits the surface of the lithium metal film 111 from being hydrated or nitrided by exposure to the atmosphere.

The lithium carbonate layer 113 of the laminated film 11 is disposed to face a positive electrode through an electrolyte, and thus a lithium metal battery is formed. The lithium metal battery may be a primary battery or a secondary battery. The positive electrode is formed of, for example, an oxide material such as LiNiO₂, LiMnO₂, or LiCoO₂.

In this embodiment, the gas containing carbon and oxygen is discharged, and the surface of the lithium metal film 111 formed on the base material 10 is exposed to this discharge gas 50. Then, a lithium carbonate layer 113 on the surface of the lithium metal film 111 is formed by modifying the surface of the lithium metal film 111 with the discharge gas 50.

The discharge gas 50 is more active than a non-discharge gas (gas in which a gas containing carbon and oxygen is not discharged), and has a higher reactivity with the lithium metal film 111 than the non-discharge gas. In other words, the surface of the lithium metal film 111 is directly carbonated by the discharge gas 50 for which discharge conditions are adjusted. Accordingly, the entire surface region of the lithium metal film 111 is carbonated quickly and uniformly. As a result, a lithium carbonate layer 113 having a desired thickness is uniformly formed on the surface of the lithium metal film 111.

For example, it was confirmed that the time taken to carbonate the surface of the lithium metal film 111 in the case of using the discharge gas 50 is reduced to approximately ⅓ of the time taken in the case of using the non-discharge gas. In this case, it is assumed that the thickness of the lithium carbonate layer 113 formed on the surface of the lithium metal film 111 is the same in the case of using the non-discharge gas and the case of using the discharge gas 50.

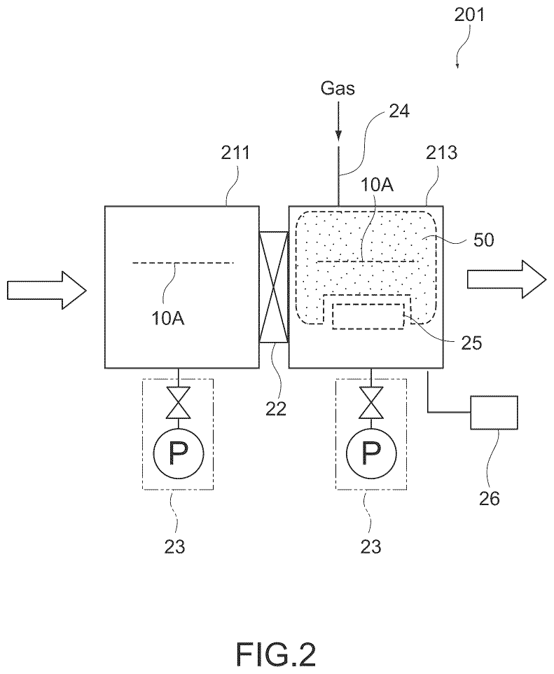

Next, description will be given on an example of a vacuum treatment apparatus that modifies the surface of the lithium metal film 111 into the lithium carbonate layer 113. FIG. 2 is a schematic configuration diagram showing an example of a vacuum treatment apparatus of this embodiment.

A vacuum treatment apparatus 201 includes a deposition unit 211 and a plasma treatment unit 213. The deposition unit 211 and the plasma treatment unit 213 are connected to each other in sequence via a gate valve 22. The deposition unit 211 and the plasma treatment unit 213 can each be depressurized to a predetermined pressure (e.g., 1×10⁻⁵ Pa or less) via an evacuation apparatus 23. A load-lock chamber (not shown) for loading may be installed on the base material loading side of the deposition unit 211, and a load-lock chamber (not shown) for unloading may be installed on the base material unloading side of the plasma treatment unit 213.

The deposition unit 211 includes an evaporation source (not shown) from which a lithium metal evaporates. In the deposition unit 211, a lithium metal film 111 is formed on a loaded sheet-like base material 10A. The plasma treatment unit 213 includes a gas supply unit 24 that can introduce a gas containing carbon and oxygen, a discharge electrode 25 that discharges the gas containing carbon and oxygen, and a power supply 26 that supplies discharge power to the discharge electrode 25. The discharge gas 50 is discharged between the discharge electrode 25 and a vacuum chamber including the plasma treatment unit 213 or between the discharge electrode and the base material 10A, and the discharge gas 50 spreads in the entire interior of the plasma treatment unit 213.

In the plasma treatment unit 213, the surface of the lithium metal film 111 is carbonated by the discharge gas 50, and a lithium carbonate layer 113 is formed on the surface of the lithium metal film 111. For example, when the surface of the lithium metal film is modified into a lithium carbonate layer, the plasma treatment unit 213 can be maintained in a reduced-pressure atmosphere of 1×10⁻² Pa or more and 1×10¹ Pa or less.

Further, the vacuum treatment apparatus 201 includes a conveyance mechanism (not shown) that sequentially conveys the base material 10A to the deposition unit 211 and the plasma treatment unit 213 via the gate valve 22. Accordingly, the deposition of the lithium metal film 111 and the formation of the lithium carbonate layer 113 are continuously and sequentially performed.

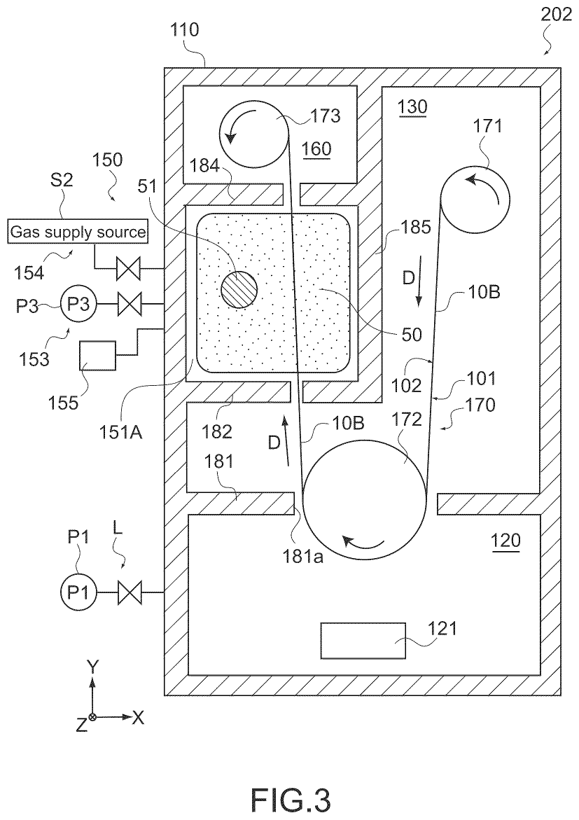

FIG. 3 is a schematic configuration diagram showing another example of the vacuum treatment apparatus of this embodiment. A vacuum treatment apparatus 202 shown in FIG. 3 is, for example, a roll-to-roll vacuum treatment apparatus.

The vacuum treatment apparatus 202 includes a vacuum chamber 110, a deposition unit 120, a conveyance unit 130, a plasma treatment unit 150, a collection unit 160, and a conveyance mechanism 170.

The vacuum chamber 110 has a hermetically sealed structure and is connected to an exhaust line L including a vacuum pump P1. The vacuum chamber 110 includes a plurality of partition panels 181, 182, 184, and 185 that partition the deposition unit 120, the conveyance unit 130, a plasma treatment chamber 151A, and the collection unit 160, respectively. The interior of the vacuum chamber 110 (deposition unit 120, conveyance unit 130, plasma treatment chamber 151A, and collection unit 160) is exhausted to a predetermined pressure or below, or maintained in a reduced-pressure atmosphere of a predetermined pressure.

The deposition unit 120 is a deposition chamber partitioned by the partition panel 181 and the outer wall of the vacuum chamber 110. An evaporation source 121 is disposed inside the deposition unit 120. The evaporation source 121 is an evaporation source from which a lithium metal evaporates. For example, a resistance-heating evaporation source, an induction-heating evaporation source, an electron-beam-heating evaporation source, or the like is applicable. Accordingly, a lithium metal film is deposited on a first main surface 101 of a base material 10B.

The deposition unit 120 is connected to the exhaust line L. When the vacuum chamber 110 is exhausted, the deposition unit 120 is first exhausted. Meanwhile, the deposition unit 120 is communicated with the conveyance unit 130, and thus the conveyance unit 130 is also exhausted when the deposition unit 120 is exhausted. Accordingly, a pressure difference is generated between the deposition unit 120 and the conveyance unit 130. This pressure difference inhibits the vapor flow of the lithium material from entering the conveyance unit 130.

The conveyance unit 130 functions as a conveyance chamber partitioned by the partition panels 181, 182, and 185 and the outer wall of the vacuum chamber 110. The conveyance unit 130 is disposed in the upper part of the vacuum chamber 110 in a Y-axis direction. FIG. 3 shows an example of the first exhaust line L connected to the deposition unit 120. The conveyance unit 130 and the deposition unit 120 may be independently exhausted by connecting another exhaust line to the conveyance unit 130.

The plasma treatment unit 150 includes the plasma treatment chamber 151A, a discharge electrode 51, a power source 155, a gas supply unit 154, and an exhaust line 153. The plasma treatment unit 150 is disposed between a main roller 172 and a wind roller 173 in a direction D in which the base material 10B is conveyed. In the plasma treatment unit 150, a gas containing carbon and oxygen is discharged between the discharge electrode 51 and the partition panels 182, 184, and 185 and vacuum chamber 110 forming the plasma treatment unit 150, or between the discharge electrode 51 and the base material 10B. Accordingly, the discharge gas 50 spreads in the entire interior of the plasma treatment chamber 151A. The surface of the lithium metal film formed on the base material 10B is exposed to the discharge gas 50 obtained by discharging the gas containing carbon and oxygen, and a lithium carbonate layer is formed on the surface of the lithium metal film.

The discharge electrode 51 is a rod-like or tubular electrode. The discharge electrode 51 extends in the width direction of the base material 10B (in a direction orthogonal to the direction D in which the base material 10B is conveyed). The outline of the cross-sectional shape of the discharge electrode 51 is, for example, circular. The length of the discharge electrode 51 is configured to be equal to or longer than the width of the base material 10B. The discharge electrode 51 may be rotated about its central axis as necessary. Further, the number of discharge electrodes of this embodiment is not limited to one, and at least one discharge electrode may be disposed for at least one of the first main surface 101 of the base material 10B or a second main surface 102 opposite to the first main surface 101. This configuration is described below.

The discharge electrode according to this embodiment is made of, for example, stainless steel. The discharge electrode may contain a metal that forms an alloy with a lithium metal film. For example, the surface of the discharge electrode may be coated with a metal layer that forms an alloy with a lithium metal film. Thus, sputtering particles scattered from the discharge electrode form a lithium alloy with the lithium metal film 111. If such a lithium metal film is applied as part of components of a lithium ion battery, the influence on the battery characteristics of the lithium ion battery is more suppressed. Further, a magnet may be disposed inside the discharge electrode in order to achieve magnetron discharge.

The power source 155 supplies the discharge power for forming the discharge gas 50 to the discharge electrode 51. The discharge power supplied from the power source 155 to the discharge electrode is one of direct-current (DC) power, alternating-current (AC) power, or radio frequency power (RF power).

The gas supply unit 154 supplies a gas containing carbon and oxygen to the internal space (plasma treatment chamber 151A) of the plasma treatment unit 150. The plasma treatment chamber 151A is connected to a gas supply source S2. The gas containing carbon and oxygen is stored in the gas supply source S2. For example, a plurality of gas supply sources S2 may be disposed, and carbon monoxide; carbon dioxide; hydrocarbons and oxygen or ozone; and combinations of those gases, and a noble gas may be independently supplied to the plasma treatment chamber 151A. For example, if a mixed gas containing carbon dioxide/argon is used, a mixed gas in which the concentration of carbon dioxide is 5% or more is supplied to the plasma treatment chamber 151A.

The plasma treatment chamber 151A is connected to an exhaust line 153 including a pump P3. The plasma treatment chamber 151A is configured to be capable of maintaining a predetermined reduced-pressure atmosphere. For example, the plasma treatment chamber 151A can be evacuated to 1×10⁻⁵ Pa or less. Further, the plasma treatment chamber 151A can maintain a reduced-pressure atmosphere of 1×10⁻² Pa or more and 1×10¹ Pa or less when the surface of the lithium metal film is modified into a lithium carbonate layer.

The conveyance mechanism 170 includes a wind-off roller 171, the main roller 172, and the wind roller 173. The main roller 172 is provided between the wind-off roller 171 and the wind roller 173 in a conveyance direction D of the base material 10B. The wind-off roller 171 rolls out the base material 10B toward the main roller 172. The main roller 172 winds and conveys the base material 10B between the wind-off roller 171 and the wind roller 173. The wind roller 173 winds the base material 10B wound and conveyed by the main roller 172.

The wind-off roller 171, the main roller 172, and the wind roller 173 include a rotary drive system (not shown). Each of the wind-off roller 171, the main roller 172, and the wind roller 173 is configured to be rotatable about the Z axis at a predetermined rotational speed. Accordingly, the base material 10B is conveyed from the wind-off roller 171 toward the wind roller 173 at a predetermined conveyance speed in the vacuum chamber 110.

Further, in the main roller 172, a portion of the lower part in the Y-axis direction faces the deposition unit 120 through an opening 181a provided in the partition panel 181. The main roller 172 is disposed at a predetermined distance from the opening 181a and faces the evaporation source 121 in the Y-axis direction.

The main roller 172 is made of a metal material such as stainless steel, iron, or aluminum and formed into a cylindrical shape. A temperature control mechanism (not shown) such as a temperature control medium circulation system may be provided inside the main roller 172. The size of the main roller 172 is not limited. For example, the width dimension of the main roller 172 in the Z-axis direction is set to be larger than the width dimension of the base material 10B in the Z-axis direction.

The base material 10B is, for example, a long film that is cut to have a predetermined width. The thickness of the base material 10B is not particularly limited and is, for example, several micrometers (μm) or more and several 10 micrometers (μm) or less. Further, the width and length of the base material 10B are also not particularly limited and can be appropriately determined depending on applications.

According to the vacuum treatment apparatus 202 configured as described above, the lithium carbonate layer 113 is formed on the surface of the lithium metal film 111 while the base material 10B is being conveyed from the deposition unit 120 toward the plasma treatment unit 150. For example, the deposition of the lithium metal film 111 on the base material 10B in the deposition unit 120 and the formation of the lithium carbonate layer 113 in the plasma treatment unit 150 (plasma treatment chamber 151A) can be performed continuously in the vacuum chamber 110.

Since the surface of the lithium metal film 111 is directly carbonated by the discharge gas 50 for which discharge conditions are adjusted, the entire surface region of the lithium metal film 111 is carbonated quickly and uniformly. This makes it possible to increase the conveyance speed at which the base material 10B is conveyed. For example, the conveyance speed at which the base material 10B is conveyed in this embodiment is 1 m/min or more and 20 m/min or less; at higher speeds, 5 m/min or more and 20 m/min or less; at much higher speeds, 10 m/min or more and 20 m/min or less; and at still higher speeds, 15 m/min or more and 20 m/min or less.

Note that in order to form the lithium oxide film 112 and lithium carbonate layer 113 having a predetermined thickness, a plurality of guide rollers may be disposed in the plasma treatment chamber 151A to adjust the path of the base material 10B that passes through the plasma treatment chamber 151A to any length.

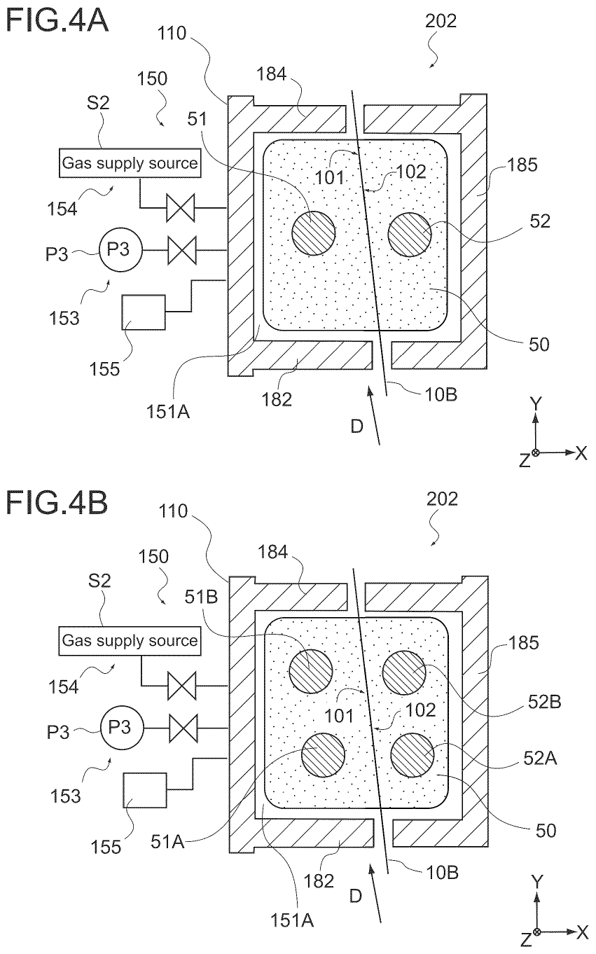

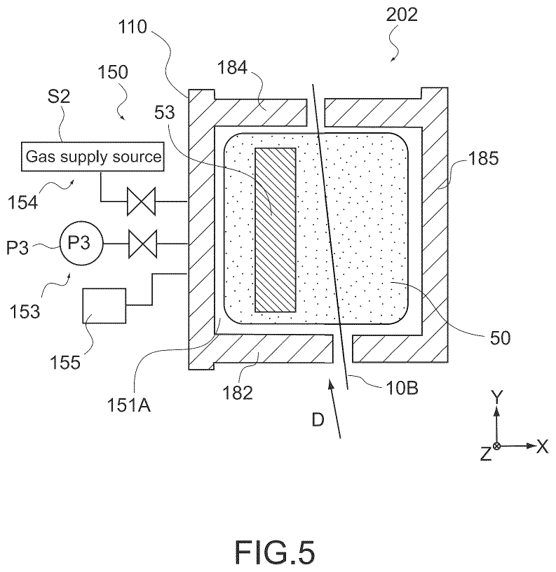

FIGS. 4A, 4B, and 5 are schematic cross-sectional views showing other examples of the plasma treatment chamber of this embodiment. The configurations of plasma treatment chambers respectively shown in FIGS. 4A, 4B, and 5 are other examples of the plasma treatment chamber 151A of the vacuum treatment apparatus 202. The configurations of plasma treatment chambers respectively shown in FIGS. 4A, 4B, and 5 are also applicable to the plasma treatment unit 213 shown in FIG. 2.

In the example shown in FIG. 4A, a pair of discharge electrodes 51 and 52 is disposed in the plasma treatment chamber 151A with the base material 10B being sandwiched therebetween. Each of the paired discharge electrodes 51 and 52 may be rotated about its own central axis as necessary. The pair of discharge electrodes 51 and 52 is disposed in the plasma treatment chamber 151A, which increases the plasma density of the discharge gas 50 and makes it easier for the discharge gas 50 to spread in the plasma treatment chamber 151A.

Accordingly, the surface of the lithium metal film 111 is carbonated more efficiently. Further, since the base material 10B is sandwiched by the pair of discharge electrodes 51 and 52, when the lithium metal film 111 is deposited on both the first main surface 101 and the second main surface 102 of the base material 10B, the lithium metal films 111 formed on both surfaces can be carbonated simultaneously and efficiently.

In the example shown in FIG. 4B, in the discharge electrodes that sandwich the base material 10B in the plasma treatment chamber 151A, the discharge electrodes facing the first main surface 101 include discharge electrodes 51A and 51B, and the discharge electrodes facing the second main surface 102 include discharge electrodes 52A and 52B. The discharge electrodes 51A and 51B are aligned in the conveyance direction D, and the discharge electrodes 52A and 52B are aligned in the conveyance direction D. Further, each of the discharge electrodes 51A, 51, 52A, and 52B may be rotated about its own central axis as necessary.

The number of discharge electrodes facing both the main surfaces of the base material 10B is increased in such a manner, which increases the plasma density of the discharge gas 50 more and makes it much easier for the discharge gas 50 to spread in the plasma treatment chamber 151A.

This allows the surface of the lithium metal film 111 to be carbonated more efficiently. Further, since the base material 10B is sandwiched between a set of discharge electrodes 51A and 51B and a set of discharge electrodes 52A and 52B, when the lithium metal films 111 are deposited on both the first main surface 101 and the second main surface 102 of the base material 10B, the lithium metal films 111 formed on both surfaces can be carbonated simultaneously and more efficiently.

In the example shown in FIG. 5, a flat-plate discharge electrode 53 is disposed in the plasma treatment chamber 151A. The discharge electrode 53 is disposed in the plasma treatment chamber 151A, which increases the area of the electrode and increases the plasma density of the discharge gas 50. This makes it easier for the discharge gas 50 to spread in the plasma treatment chamber 151A and to efficiently carbonate the surface of the lithium metal film 111.

Further, the thickness of the lithium metal film may be 5 nm or more and 100 nm or less. Even in such a case, the lithium metal film formed on the base material 10 (base materials 10A and 10B) by the vacuum treatment apparatuses 201 and 202 is carbonated by the discharge gas 50.

Further, the discharge electrode may contain a metal that forms an alloy with the lithium metal film. For example, the surface of the discharge electrode may be coated with a metal layer that forms an alloy with the lithium metal film. The examples of metals that form alloys with the lithium metal film include C, Mg, Al, Si, Ti, Fe, Ni, Zn, Ag, Sn, and alloys of those metals. Accordingly, sputtering particles scattered from the discharge electrode form a lithium alloy with the lithium metal film. If such a lithium metal film is applied as part of components of a lithium ion battery, the influence on the battery characteristics of the lithium ion battery is more suppressed.

Hereinabove, the embodiment of the present invention has been described, but the present invention is not limited to the embodiment described above, but can of course be modified in various ways. Each embodiment is not necessarily an independent form, but can be combined as much as technically possible.

It should be understood by those skilled in the art that various modifications, combinations, sub-combinations and alterations may occur depending on design requirements and other factors insofar as they are within the scope of the appended claims or the equivalents thereof.

What is claimed is:

1. A vacuum treatment apparatus, comprising:
a deposition unit that includes an evaporation source including a lithium metal and forms a lithium metal film on a base material; and
a plasma treatment unit that exposes a surface of the lithium metal film formed on the base material to a discharge gas obtained by discharging a gas containing carbon and oxygen, and forms a lithium carbonate layer on the surface.

2. The vacuum treatment apparatus according to claim 1, wherein
the lithium carbonate layer is formed on the surface while the base material is being conveyed from the deposition unit toward the plasma treatment unit, and
a conveyance speed at which the base material is conveyed is 1 m/min or more.

3. The vacuum treatment apparatus according to claim 1, wherein
the base material is foil-like,
the vacuum treatment apparatus further comprises:
a wind-off roller that winds off the base material;
a wind roller that winds the base material; and
a main roller provided between the wind-off roller and the wind roller in a conveyance direction in which the base material is conveyed, and winds and conveys the base material, and
the plasma treatment unit is disposed between the main roller and the wind roller in the conveyance direction.

4. The vacuum treatment apparatus according to claim 1, wherein
the plasma treatment unit includes
at least one discharge electrode that extends in a width direction of the base material and faces at least one of a first main surface of the base material or a second main surface opposite to the first main surface,
a gas supply unit that supplies the gas to an internal space of the plasma treatment unit, and
a power supply that supplies discharge power to the discharge electrode.

5. The vacuum treatment apparatus according to claim 4, wherein
a surface of the discharge electrode includes C, Mg, Al, Si, Ti, Fe, Ni, Zn, Ag, Sn, and an alloy of those metals.

6. A vacuum treatment method, comprising:
forming a lithium metal film on a base material by using an evaporation source including a lithium metal; and
exposing a surface of the lithium metal film formed on the base material to a discharge gas obtained by discharging a gas containing carbon and oxygen, and forms a lithium carbonate layer on the surface.

7. The vacuum treatment method according to claim 6, wherein
the lithium carbonate layer is formed on the surface continuously after the lithium metal film is formed on the base material with a reduced pressure state being maintained.

8. The vacuum treatment method according to claim 6, wherein
the lithium carbonate layer is formed on the surface while the base material is being conveyed from a deposition unit toward a plasma treatment unit, and
a conveyance speed at which the base material is conveyed is set to 1 m/min or more.

9. The vacuum treatment method according to claim 6, wherein
the base material is foil-like, and
the lithium carbonate layer is formed on the surface by a roll-to-roll method.

10. The vacuum treatment method according to claim 7, wherein
the lithium metal film having a thickness of 1 μm or more and 20 μm or less is formed on the base material, and
the lithium carbonate layer having a thickness of 5 nm or more and 30 nm or less is formed.
